(19) United States
(12) Patent Application Publication
(10) Pub. No.: US 2026/0033352 A1
(43) Pub. Date: Jan. 29, 2026

(54) PACKAGE COMPRISING AN INTEGRATED DEVICE WITH BACK SIDE METALLIZATION INTERCONNECTS

(71) Applicant: QUALCOMM Incorporated, San Diego, CA (US)

(72) Inventors: Aniket PATIL, San Diego, CA (US); Bohan YAN, San Diego, CA (US); Zhijie WANG, San Diego, CA (US)

(21) Appl. No.: 18/781,723

(22) Filed: Jul. 23, 2024

(51) Int. Cl. H01L 23/538; H01L 23/00; H01L 23/13; H01L 23/31; H01L 23/498; H01L 25/00; H01L 25/10

(52) U.S. Cl. CPC H01L 23/5385; H01L 23/13; H01L 23/3107; H01L 23/49811; H01L 23/49822; H01L 24/16; H01L 24/17; H01L 24/32; H01L 24/73; H01L 25/105; H01L 25/50; H01L 2224/16227; H01L 2224/17181; H01L 2224/32225; H01L 2224/73204; H01L 2224/73253; H01L 2225/1041

(57) ABSTRACT

A package comprising a first substrate; an integrated device coupled to the first substrate, wherein the integrated device comprises a plurality of back side metallization interconnects; and a second substrate coupled to the first substrate through a first plurality of solder interconnects, wherein the second substrate is coupled to the plurality of back side metallization interconnects through the second plurality of solder interconnects.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with substrates and integrated devices.

One example provides a package comprising a first substrate; an integrated device coupled to the first substrate, wherein the integrated device comprises a plurality of back side metallization interconnects; and a second substrate coupled to the first substrate through a first plurality of solder interconnects, wherein the second substrate is coupled to the plurality of back side metallization interconnects through the second plurality of solder interconnects.

A method for fabricating a package. The method provides a first substrate. The method couples an integrated device to the first substrate, wherein the integrated device comprises a plurality of back side metallization interconnects. The method couples a second substrate to the first substrate through a first plurality of solder interconnects, wherein the second substrate is coupled to the plurality of back side metallization interconnects through a second plurality of solder interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a first substrate, a second substrate, and an integrated device with back side metallization interconnects.

FIG. 2 illustrates an exemplary cross sectional profile view of a package that includes a first substrate, a second substrate, and an integrated device with back side metallization interconnects.

FIG. 3 illustrates an exemplary cross sectional plan view of a package that includes a first substrate, a second substrate, and an integrated device with back side metallization interconnects.

FIG. 4 illustrates an exemplary cross sectional profile view of a package that includes a first substrate, a second substrate, and an integrated device with back side metallization interconnects.

FIG. 5 illustrates an exemplary cross sectional profile view of a package that includes a first substrate, a second substrate, and an integrated device with back side metallization interconnects.

FIGS. 6A-6B illustrate an exemplary sequence for fabricating a package that includes a first substrate, a second substrate, and an integrated device with back side metallization interconnects.

FIG. 7 illustrates an exemplary sequence for fabricating a package that includes a first substrate, a second substrate, and an integrated device with back side metallization interconnects.

FIG. 8 illustrates an exemplary flow chart of a method for fabricating a package that includes a first substrate, a second substrate, and an integrated device with back side metallization interconnects.

FIGS. 9A-9B illustrate an exemplary sequence for fabricating a substrate.

FIG. 10 illustrates an exemplary flow chart of a method for fabricating a substrate.

FIG. 11 illustrates an exemplary flow chart of a method for fabricating a package that includes a first substrate, a second substrate, and an integrated device with back side metallization interconnects.

FIG. 12 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a first substrate; an integrated device coupled to the first substrate, wherein the integrated device comprises a plurality of back side metallization interconnects; and a second substrate coupled to the first substrate through a first plurality of solder interconnects, wherein the second substrate is coupled to the plurality of back side metallization interconnects through the second plurality of solder interconnects. In some implementations, the configuration of the package helps minimize, reduce and/or keep the size of the package as small as possible.

### Exemplary Package Comprising a Substrate Coupled to a Back Side of an Integrated Device

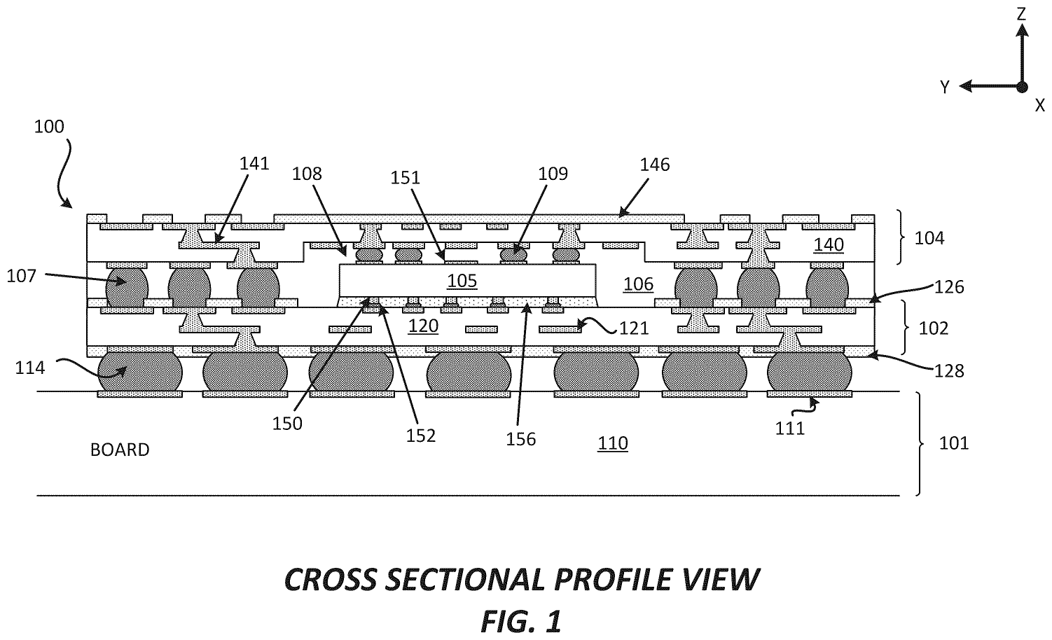

FIG. 1 illustrates a cross sectional profile view of a package 100 that includes a substrate coupled to a back side of an integrated device. The package 100 may be implemented as part of a package on package (PoP). The package 100 is coupled to a board 101 through a plurality of solder interconnects 114. The board 101 includes at least one board dielectric layer 110 and a plurality of board interconnects 111. The board 101 may include a printed circuit board (PCB).

The package 100 includes a substrate 102, an integrated device 105, a substrate 104, an encapsulation layer 106, a plurality of solder interconnects 107, and a plurality of solder interconnects 109. The substrate 102 may be a first substrate. The substrate 104 may be a second substrate. The substrate 102 may be a laminated substrate. The substrate 104 may be a laminated substrate. The substrate 104 may be an interposer (e.g., package interposer). The integrated device 105 includes a plurality of back side metallization interconnects 151. The integrated device 105 includes a die substrate (e.g., silicon die substrate). The plurality of back side metallization interconnects 151 is formed on a back side surface of the die substrate of the integrated device 105.

The substrate 102 includes at least one dielectric layer 120, a plurality of interconnects 121, a solder resist layer 126 and a solder resist layer 128. The integrated device 105 may be coupled to a first surface of the substrate 102 through a plurality of pillar interconnects 150 and/or a plurality of solder interconnects 152. For example, the integrated device 105 may be coupled to interconnects from the plurality of interconnects 121 of the substrate 102, through a plurality of pillar interconnects 150 and a plurality of solder interconnects 152. An underfill 156 may be located vertically between the integrated device 105 and the substrate 102. The underfill 156 may include a composite material comprising an epoxy polymer with filler.

The substrate 104 is coupled to the substrate 102 through the plurality of solder interconnects 107. The plurality of solder interconnects 107 may be a first plurality of solder interconnects. The substrate 104 includes at least one dielectric layer 140, a plurality of interconnects 141 and a solder resist layer 146. The plurality of solder interconnects 107 may be coupled to and touch (i) the plurality of interconnects 121 of the substrate 102 and (ii) the plurality of interconnects 141 of the substrate 104. The plurality of solder interconnects 107 may be located vertically between the substrate 102 and the substrate 104. In some implementations, the substrate 104 may be coupled to the substrate 102 through the plurality of solder interconnects 107 and a plurality of ball interconnects (e.g., copper balls). The substrate 104 may be coupled to a back side of the integrated device 105. For example, the substrate 104 may be coupled to the back side of the integrated device 105 through the plurality of solder interconnects 109. The plurality of solder interconnects 109 may be a second plurality of solder interconnects. The plurality of solder interconnects 109 may be coupled to and touch (i) the plurality of back side metallization interconnects 151 and (ii) the plurality of interconnects 141.

The encapsulation layer 106 is located vertically between the substrate 102 and the substrate 104. The encapsulation layer 106 may be coupled to and touching the substrate 102 and the substrate 104. The encapsulation layer 106 may at least partially encapsulate the integrated device 105, the plurality of solder interconnects 107 and/or the plurality of solder interconnects 109. The encapsulation layer 106 may include a mold, a resin, an epoxy and/or a filler. The encapsulation layer 106 may include a different material and/or a different composition from the underfill 156.

The substrate 104 includes a cavity 108. The cavity 108 may be at least partially occupied by the encapsulation layer 106 and/or the plurality of solder interconnects 109. Thus, the plurality of solder interconnects 109 and/or a portion of the encapsulation layer 106 may be located at least partially in the cavity 108 of the substrate 104. In some implementations, a part of the integrated device 105 may be located in the cavity 108 of the substrate 104. In some implementations, the cavity 108 may still be considered a cavity of the substrate 104, even if the cavity 108 is filled and/or occupied with a material and/or a component that is separate and/or different from the substrate 104. The substrate 104 may have a first portion with a first thickness and a second portion with a second thickness that is different from the first thickness. For example, the first portion of the substrate 104 may include a portion that does not vertically overlap with the integrated device 105, and the second portion of the substrate 104 may include a portion that vertically overlaps with the integrated device 105. The portion of the substrate 104 that vertically overlaps with the integrated device 105 may include a second thickness that is less than a first thickness of the portion of the substrate 104 that does not vertically overlaps with the integrated device 105.

The integrated device 105 may have different thicknesses and/or heights. Similarly, the plurality of solder interconnects 107 may have different heights and/or pitch. For example, the presence of the cavity 108 may allow the substrate 104 to be closer to the substrate 102, which would allow the size and/or the pitch of the plurality of solder interconnects 107 to be smaller. The configuration of the package 100 helps minimize, reduce and/or keep the size of the package 100 as small as possible. For example, the package 100 may have a reduced thickness due to some of the back side metallization interconnects being used as electrical paths for the package 100. The package 100 may also provide improved thermal performance (e.g., improved heat dissipation). For example, with the presence of the cavity 108 in the substrate 104, the integrated device 105 may have a thicker die substrate, while still keeping the overall thickness of the package 100 the same or less. The thicker die substrate of the integrated device 105 may help improve the thermal performance of the package 100 and/or the integrated device 105 because the die substrate (which may be a silicon die substrate) may have a thermal conductivity that is better than the thermal conductivity of the encapsulation layer 106.

The integrated device 105 may include a die substrate (e.g., silicon die substrate). The plurality of back side metallization interconnects 151 may be formed on a back side of the die substrate of the integrated device 105. In some implementations, the die substrate may be free of any through substrate vias. In some implementations, the die substrate may be free of any through substrate vias that is coupled to and touching the plurality of back side metallization interconnects 151.

In some implementations, another integrated device or another package may be coupled to the substrate 104. The integrated device (e.g., second integrated device, another integrated device) may be coupled to the substrate 104 through a plurality of solder interconnects. Another package may be coupled to the substrate 104 through a plurality of solder interconnects.

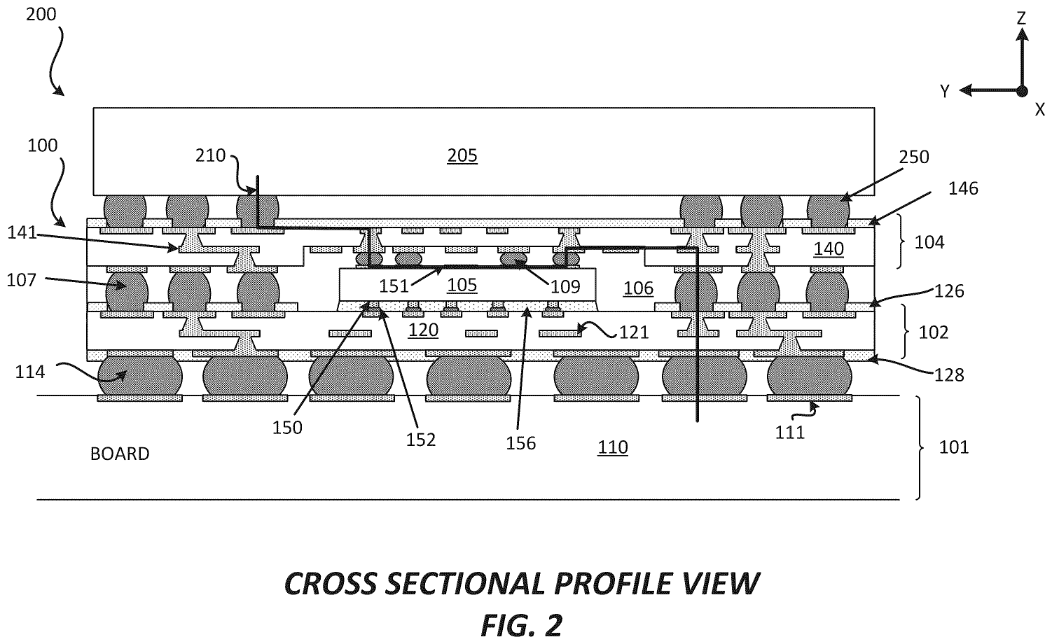

FIG. 2 illustrates a cross sectional profile view of a package 200 that includes a substrate coupled to a back side of an integrated device. The package 200 may be implemented as a package on package (PoP). The package 200 is coupled to a board 101 through a plurality of solder interconnects 114. The package 200 includes the package 100 and an integrated device 205. The package 100 of FIG. 2 may be similar to the package 100 of FIG. 1. The integrated device 205 may be a second integrated device or another integrated device. The integrated device 205 is coupled to the substrate 104 through a plurality of solder interconnects 250. The plurality of solder interconnects 250 may be a third plurality of solder interconnects. The plurality of solder interconnects 250 may be coupled to and touch the plurality of interconnects 141 of the substrate 104.

FIG. 2 illustrates the package 200 with an exemplary electrical path 210. The electrical path 210 may be an electrical path between the integrated device 205 and the board 101. The electrical path 210 includes (i) at least one solder interconnect from the plurality of solder interconnects 250, (ii) at least one interconnect from the plurality of interconnects 141, (iii) at least one solder interconnect from the plurality of solder interconnects 109, (iv) at least one back side metallization interconnect from the plurality of back side metallization interconnects 151, (v) at least one other solder interconnect from the plurality of solder interconnects 109, (vi) at least one other interconnect from the plurality of interconnects 141, (vii) at least one solder interconnect from the plurality of solder interconnects 107, (viii) at least one interconnect from the plurality of interconnects 121, (ix) at least one solder interconnect from the plurality of solder interconnects 114 and/or (x) at least one board interconnect from the plurality of board interconnects 111.

FIG. 2 illustrates an electrical path 210 that extends along a surface of the back side of the integrated device 105. However, the electrical path 210 does not extend from the back side of the integrated device 105 through the front side of the integrated device 105. For example, the electrical path 210 through the plurality of back side metallization interconnects 151 does not extend through the die substrate of the integrated device 105. The plurality of back side metallization interconnects 151 of the integrated device 105 may be configured and/or served as interconnects (e.g., metal layer) for the substrate 104. In some implementations, the plurality of back side metallization interconnects 151 may be on a same metal layer and/or a plane as a metal layer of the substrate 104. In some implementations, the plurality of back side metallization interconnects 151 may be on a plane that is between two metal layers of the substrate 104. For example, if the substrate 104 has a first metal layer (M1), a second metal (M2) and a third metal layer (M3), the plurality of back side metallization interconnects 151 may be considered to be a two and a half metal layer (e.g., M2.5). Moreover, the plurality of back side metallization interconnects 151 may have lower thicknesses than interconnects on a metal layer from the plurality of interconnects 141. In some implementations, the plurality of back side metallization interconnects 151 may have line and spacing (e.g., minimum line and/or minimum spacing) that is/are less than the line and/or spacing (e.g., minimum line and/or minimum spacing) of the plurality of interconnects 141 of the substrate 104. Thus, the plurality of back side metallization interconnects 151 may have higher interconnect densities than the plurality of interconnects 141.

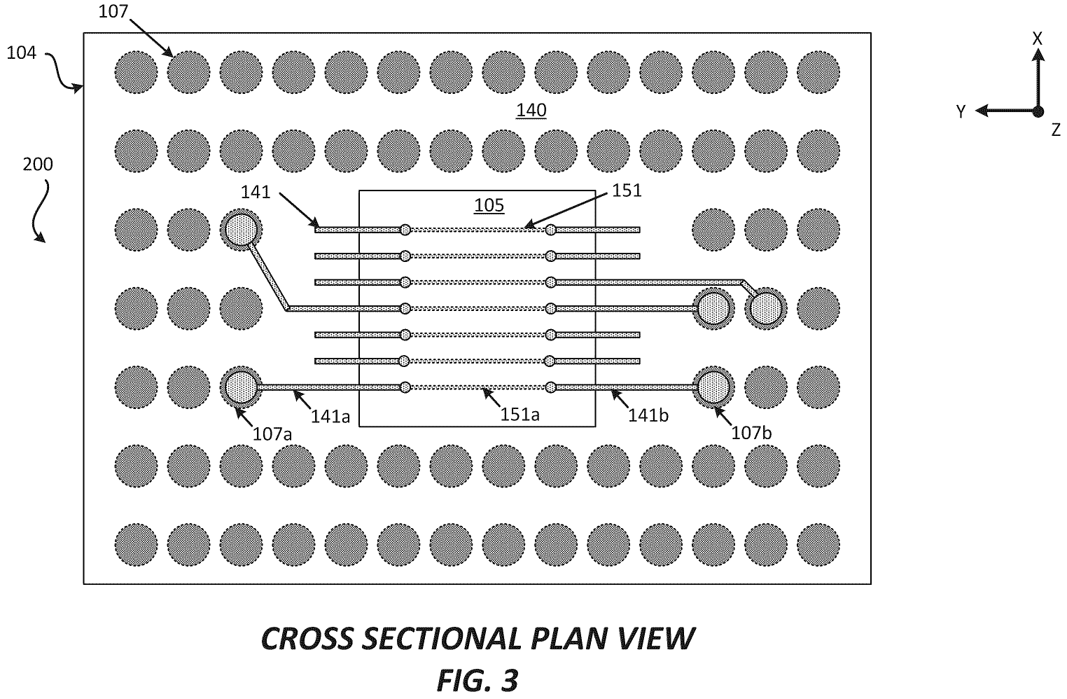

FIG. 3 illustrates an exemplary plan view of the package 200. The package 200 includes the substrate 104, the integrated device 105 and the plurality of solder interconnects 107. The substrate 104 includes the plurality of interconnects 141. The integrated device 105 includes a plurality of back side metallization interconnects 151. The plurality of solder interconnects 107 is coupled to the substrate 104. The plurality of solder interconnects 107 includes a solder interconnect 107a and a solder interconnect 107b. An electrical path between a solder interconnect 107a and a solder interconnect 107b may include a plurality of interconnects 141a, at least one back side metallization interconnect 151a from the plurality of back side metallization interconnects 151 and a plurality interconnects 141b. Thus, an electrical path may extend through interconnects of a substrate, through back side metallization interconnects and back through other interconnects of a substrate. Although not shown, a plurality of solder interconnects 109 may be coupled to the plurality of back side metallization interconnects 151 and the plurality of interconnects 141. Thus, an electrical path between a solder interconnect 107a and a solder interconnect 107b may include a plurality of interconnects 141a, at least one solder interconnect from the plurality of solder interconnects 109, at least one back side metallization interconnect 151a from the plurality of back side metallization interconnects 151, at least one other solder interconnect from the plurality of solder interconnects 109, and a plurality interconnects 141b.

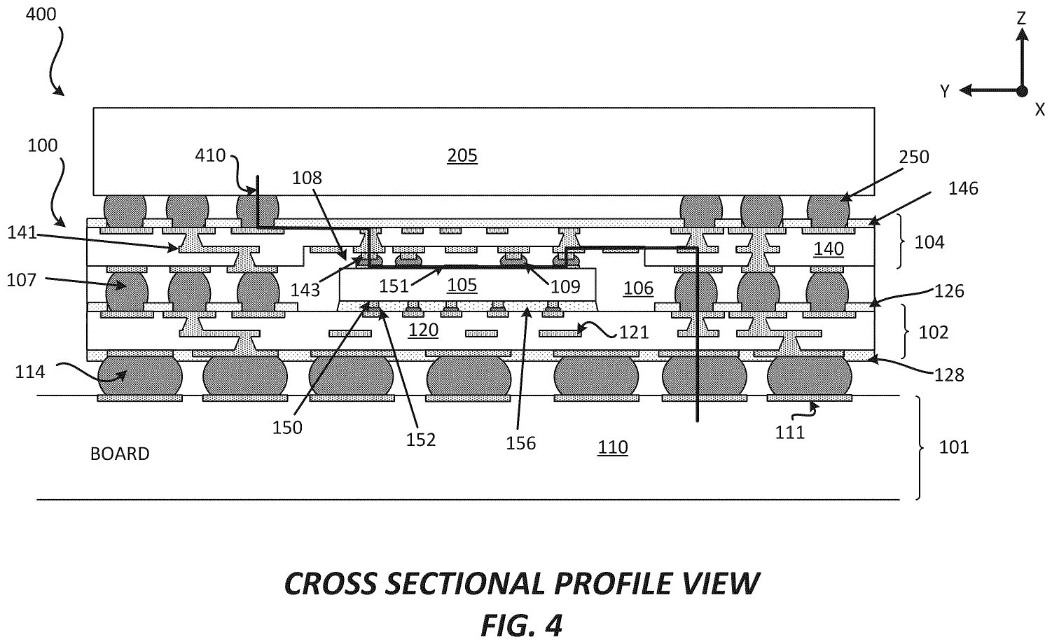

FIG. 4 illustrates a cross sectional profile view of a package 400 that includes a substrate coupled to a back side of an integrated device. The package 400 may be implemented as a package on package (PoP). The package 400 is coupled to a board 101 through a plurality of solder interconnects 114. The package 400 includes the package 100 and an integrated device 205. The package 100 of FIG. 4 may be similar to the package 100 of FIG. 1. The package 100 includes a substrate 104. The substrate 104 includes at least one dielectric layer 140, a plurality of interconnects 141, a plurality of post interconnects 143, and a solder resist layer 146. In some implementations, the plurality of post interconnects 143 may be considered part of the plurality of interconnects 141. In some implementations, the plurality of post interconnects 143 may be coupled to the plurality of interconnects 141. The integrated device 205 may be a second integrated device or another integrated device. The integrated device 205 is coupled to the substrate 104 through a plurality of solder interconnects 250. The plurality of solder interconnects 250 may be a third plurality of solder interconnects. The plurality of solder interconnects 250 may be coupled to and touch the plurality of interconnects 141 of the substrate 104.

The substrate 104 is coupled to the back side of the integrated device 105 through the plurality of solder interconnects 109. The plurality of solder interconnects 109 may be coupled to and touch (i) the plurality of back side metallization interconnects 151 and (ii) the plurality of post interconnects 143.

An electrical path 410 between the integrated device 205 and the board 101 may include (i) at least one solder interconnect from the plurality of solder interconnects 250, (ii) at least one interconnect from the plurality of interconnects 141, (iii) at least one post interconnect from the plurality of post interconnects 143, (iv) at least one solder interconnect from the plurality of solder interconnects 109, (v) at least one back side metallization interconnect from the plurality of back side metallization interconnects 151, (vi) at least one other solder interconnect from the plurality of solder interconnects 109, (vii) at least one other post interconnect from the plurality of post interconnects 143, (viii) at least one other interconnect from the plurality of interconnects 141, (ix) at least one solder interconnect from the plurality of solder interconnects 107, (x) at least one interconnect from the plurality of interconnects 121, (xi) at least one solder interconnect from the plurality of solder interconnects 114 and/or (xii) at least one board interconnect from the plurality of board interconnects 111.

In some implementations, the above mentioned electrical path 410 may extend along a surface of the back side of the integrated device 105. However, the above mentioned electrical path may not extend from the back side of the integrated device 105 through the front side of the integrated device 105. For example, the above mentioned electrical path through the plurality of back side metallization interconnects 151 may not extend through the die substrate of the integrated device 105.

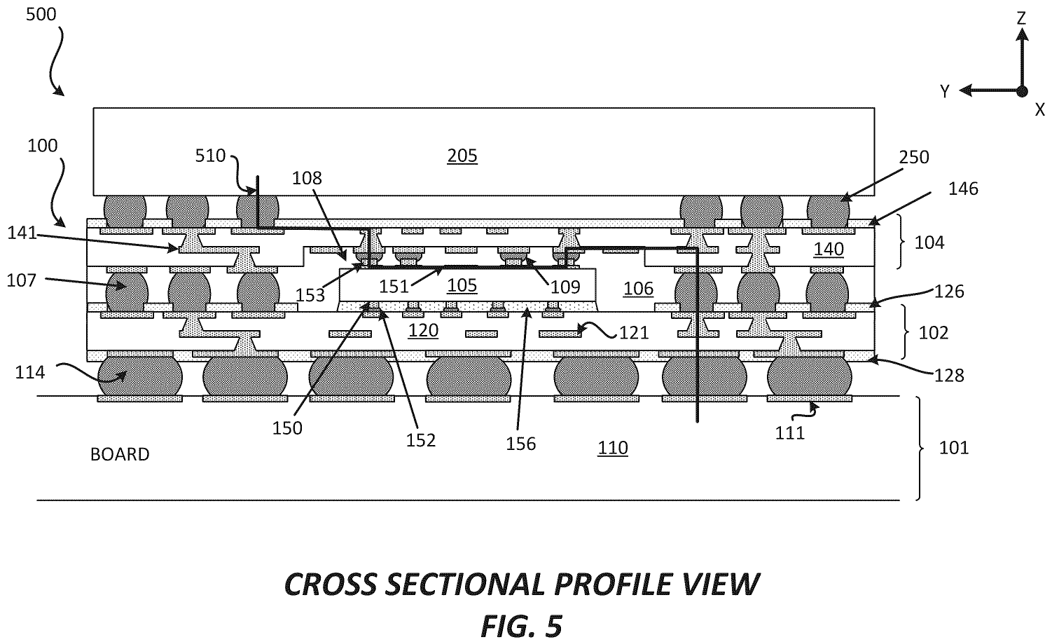

FIG. 5 illustrates a cross sectional profile view of a package 500 that includes a substrate coupled to a back side of an integrated device. The package 500 may be implemented as a package on package (PoP). The package 500 is coupled to a board 101 through a plurality of solder interconnects 114. The package 500 includes the package 100 and an integrated device 205. The package 100 of FIG. 5 may be similar to the package 100 of FIG. 1. The package 100 includes an integrated device 105. The integrated device 105 includes a plurality of back side metallization interconnects 151 and a plurality of post interconnects 153 (e.g., plurality of post back side interconnects). In some implementations, the plurality of post interconnects 153 may be coupled to the plurality of back side metallization interconnects 151. In some implementations, the plurality of post interconnects 153 may be considered part of the plurality of back side metallization interconnects 151. The integrated device 205 may be a second integrated device or another integrated device. The integrated device 205 is coupled to the substrate 104 through a plurality of solder interconnects 250. The plurality of solder interconnects 250 may be a third plurality of solder interconnects. The plurality of solder interconnects 250 may be coupled to and touch the plurality of interconnects 141 of the substrate 104.

The substrate 104 is coupled to the back side of the integrated device 105 through the plurality of solder interconnects 109. The plurality of solder interconnects 109 may be coupled to and touch (i) the plurality of post interconnects 153 and (ii) the plurality of interconnects 141. In some implementations, the plurality of solder interconnects 109 may be coupled to and touch (i) the plurality of post interconnects 153, (ii) the plurality of back side metallization interconnects 151 and (iii) the plurality of interconnects 141.

An electrical path 510 between the integrated device 205 and the board 101 may include (i) at least one solder interconnect from the plurality of solder interconnects 250, (ii) at least one interconnect from the plurality of interconnects 141, (iii) at least one solder interconnect from the plurality of solder interconnects 109, (iv) at least one post interconnect from the plurality of post interconnects 153, (v) at least one back side metallization interconnect from the plurality of back side metallization interconnects 151, (vi) at least one other post interconnect from the plurality of post interconnects 153, (vii) at least one other solder interconnect from the plurality of solder interconnects 109, (viii) at least one other interconnect from the plurality of interconnects 141, (ix) at least one solder interconnect from the plurality of solder interconnects 107, (x) at least one interconnect from the plurality of interconnects 121, (xi) at least one solder interconnect from the plurality of solder interconnects 114 and/or (xii) at least one board interconnect from the plurality of board interconnects 111.

In some implementations, the above mentioned electrical path 510 may extend along a surface of the back side of the integrated device 105. However, the above mentioned electrical path may not extend from the back side of the integrated device 105 through the front side of the integrated device 105. For example, the above mentioned electrical path through the plurality of back side metallization interconnects 151 may not extend through the die substrate the integrated device 105.

It is noted that the electrical paths shown in FIGS. 2, 4 and 5 are exemplary. Other electrical paths are possible between different interconnects and/or between different components.

An integrated device (e.g., 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 200) may be implemented in a radio frequency (RF) package. The RF package may be a radio frequency front end (RFFE) package. A package (e.g., 200) may be configured to provide Wireless Fidelity (WiFi) communication and/or cellular communication (e.g., 2G, 3G, 4G, 5G). The packages (e.g., 100) may be configured to support Global System for Mobile (GSM) Communications, Universal Mobile Telecommunications System (UMTS), and/or Long-Term Evolution (LTE). The packages (e.g., 200) may be configured to transmit and receive signals having different frequencies and/or communication protocols.

### Exemplary Sequence for Fabricating a Package

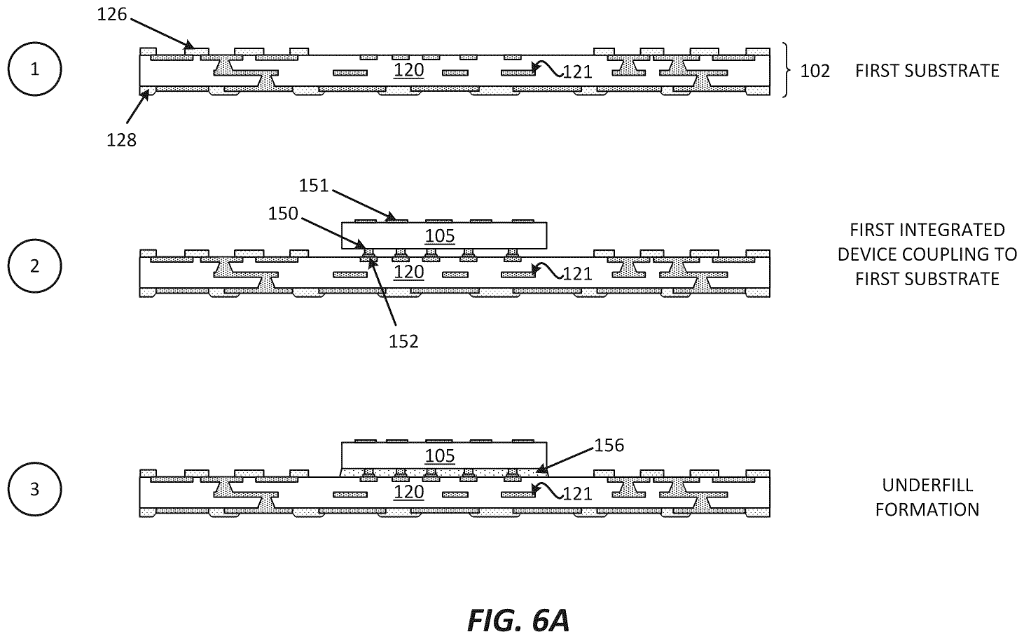

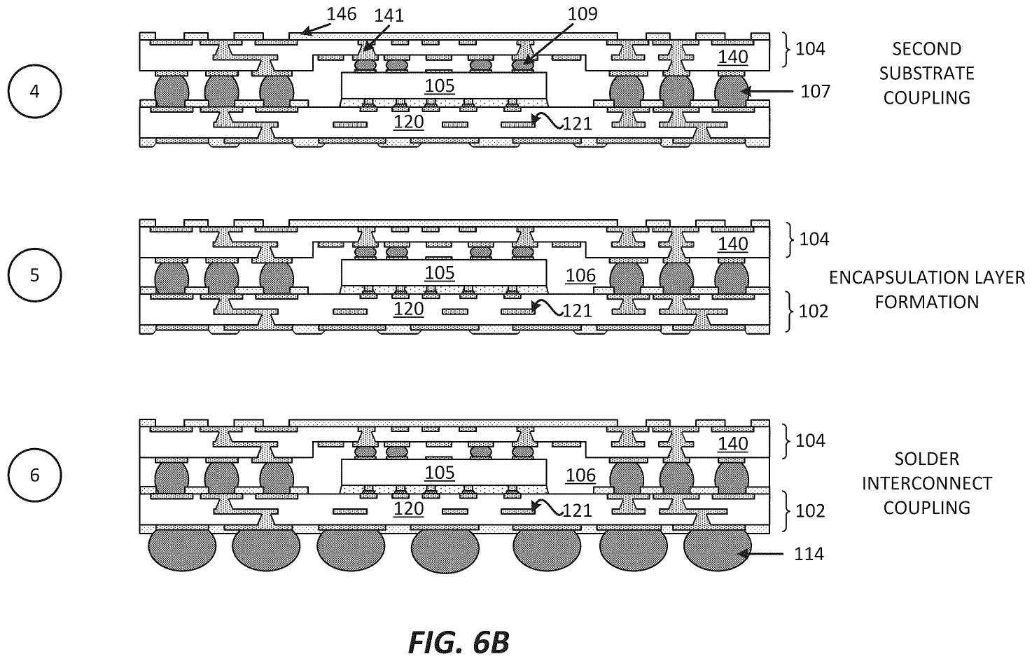

In some implementations, fabricating a package includes several processes. FIGS. 6A-6B illustrate an exemplary sequence for providing or fabricating a package. In some implementations, the sequence of FIGS. 6A-6B may be used to provide or fabricate the package 100. However, the process of FIGS. 6A-6B may be used to fabricate any of the packages described in the disclosure.

It should be noted that the sequence of FIGS. 6A-6B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

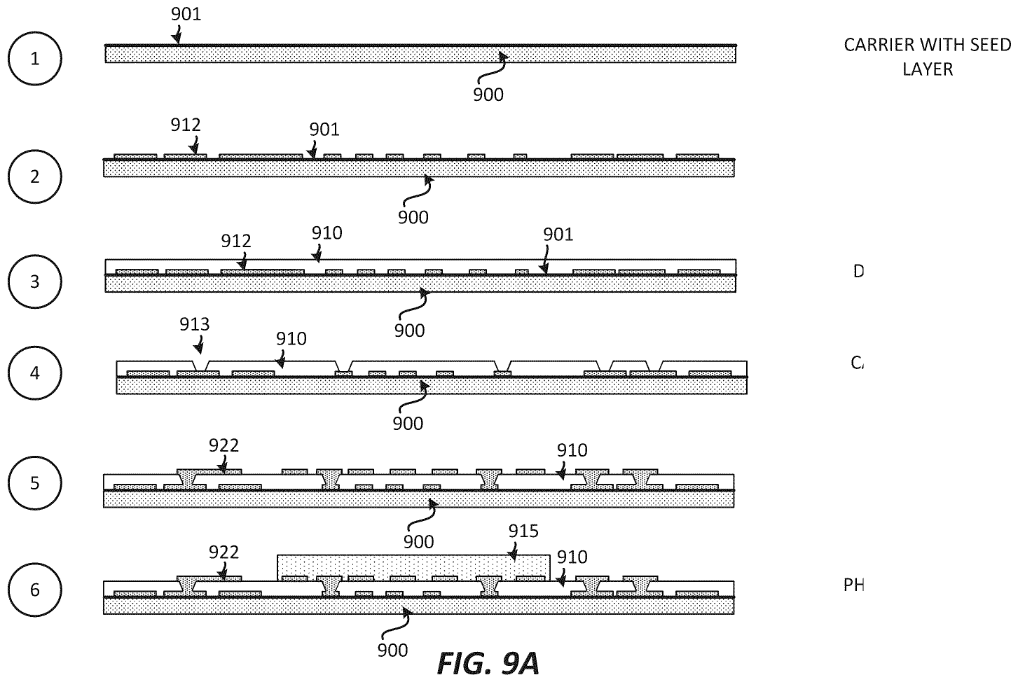

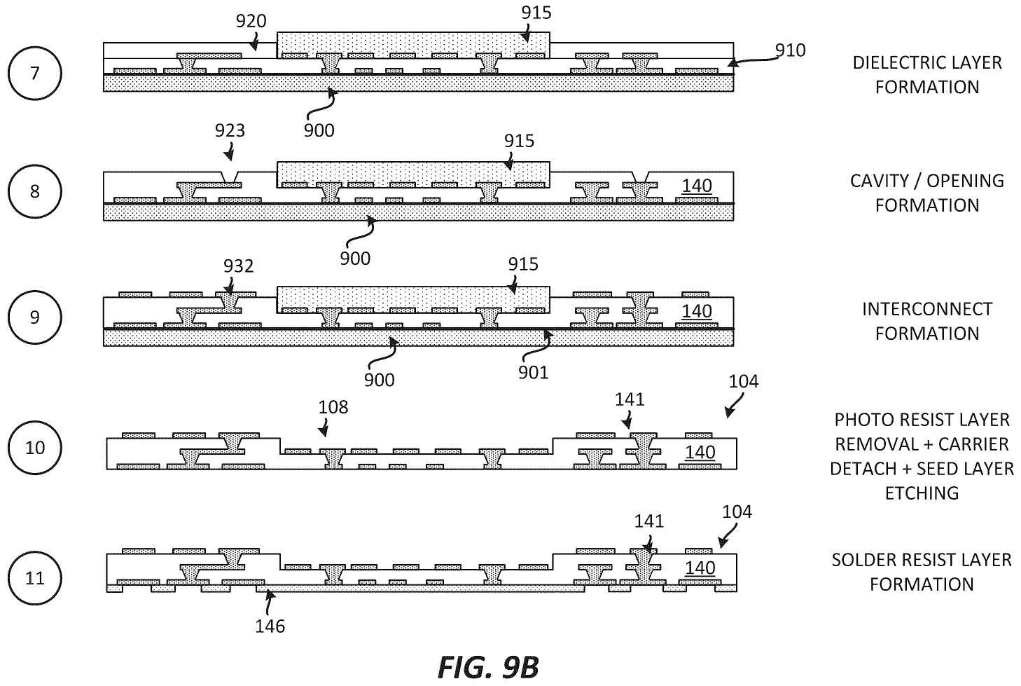

Stage 1, as shown in FIG. 6A, illustrates a state after a substrate 102 is provided. The substrate 102 may be a first substrate. The substrate 102 includes at least one dielectric layer 120, a plurality of interconnects 121, a solder resist layer 126 and a solder resist layer 128. The substrate 102 may include a first surface (e.g., top surface) and a second surface (e.g., bottom surface). The substrate 102 may be fabricated using a method similar to the method described below in FIGS. 9A-9B.

Stage 2 illustrates a state after an integrated device 105 is coupled to the first surface (e.g., top surface) of the substrate 102. The integrated device 105 may be coupled to the substrate 102 through the plurality of pillar interconnects 150 and the plurality of solder interconnects 152. In some implementations, the integrated device 105 may be coupled to the substrate 102 through the plurality of solder interconnects 152. A solder reflow process may be used to couple the integrated device 105 to the substrate 102. The integrated device 105 may include a plurality of back side metallization interconnects 151. In some implementations, the integrated device 105 may include a plurality of post interconnects 153.

Stage 3 illustrates a state after an underfill 156 is formed, dispensed and/or provided. The underfill 156 may be located vertically between the integrated device 105 and the substrate 102. A flow process may be used to provide the underfill 156.

Stage 4, as shown in FIG. 6B, illustrates a state after the substrate 104 is coupled to the substrate 102 through the plurality of solder interconnects 107. The substrate 104 may also be coupled to the back side of the integrated device 105 through the plurality of solder interconnects 109. The plurality of solder interconnects 109 may be coupled to the plurality of back side metallization interconnects 151. A solder reflow process may be used to couple the substrate 104 to the substrate 102. The substrate 104 may be a second substrate. The substrate 104 may be an interposer. The substrate 104 includes at least one dielectric layer 140 (e.g., interposer dielectric layer) and a plurality of interconnects 141 (e.g., interposer interconnects). In some implementations, the substrate 104 may include a plurality of post interconnects 143.

Stage 5 illustrates a state after an encapsulation layer 106 is provided between the substrate 102 and the substrate 104. The encapsulation layer 106 may include a mold, a resin, an epoxy and/or a filler. The encapsulation layer 106 may include a different material and/or a different composition from the underfill 156. The encapsulation layer 106 may be provided by using a compression and transfer molding process, a sheet molding process, or a liquid molding process.

Stage 6 illustrates a state after a plurality of solder interconnects 114 are coupled to the second surface of the substrate 102. A solder reflow process may be used to couple the plurality of solder interconnects 114 to the substrate 102. The plurality of solder interconnects 114 may be coupled to the plurality of interconnects 121. Stage 6 may illustrate an example of a package 100.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Package

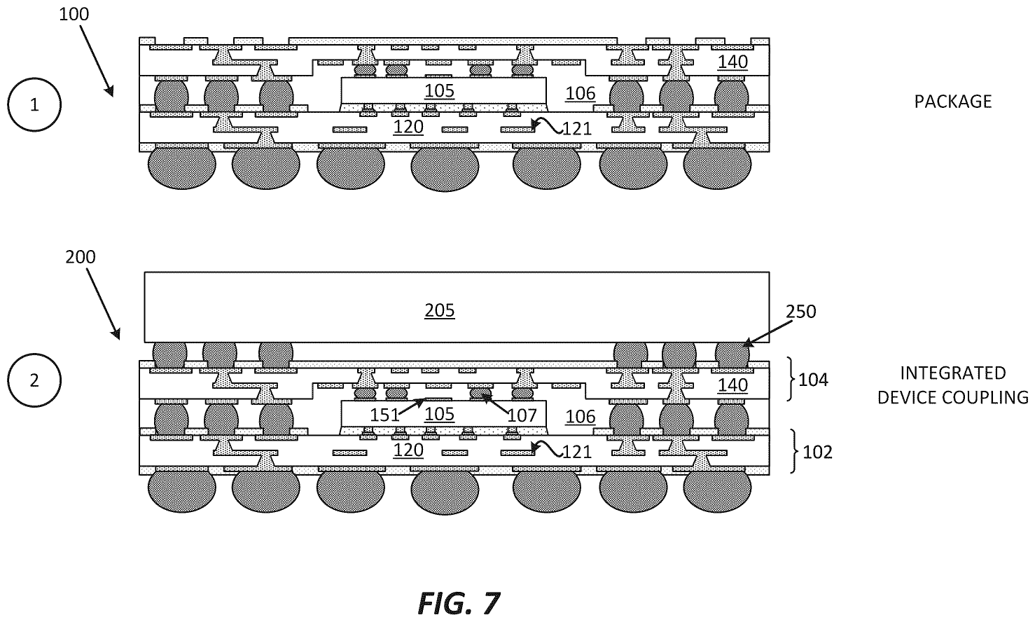

In some implementations, fabricating a package includes several processes. FIG. 7 illustrates an exemplary sequence for providing or fabricating a package. In some implementations, the sequence of FIG. 7 may be used to provide or fabricate the package 200. However, the process of FIG. 7 may be used to fabricate any of the packages described in the disclosure.

It should be noted that the sequence of FIG. 7 may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 7, illustrates a state after a package 100 that includes a substrate 102, a substrate 104, an encapsulation layer 106, and an integrated device 105, is provided. The substrate 102 may be a first substrate. The substrate 104 may be a second substrate. The substrate 104 may be an interposer. In some implementations, the package may be fabricated using the process illustrated and described in FIGS. 6A-6B.

Stage 2 illustrates a state after an integrated device 205 is coupled to the substrate 104 through a plurality of solder interconnects 250. A solder reflow process may be used to couple the integrated device 205 to the substrate 104. The integrated device 205 may each be a memory die (e.g., dynamic random access memory (DRAM) die). Instead of an integrated device, another package may be coupled to the substrate 104. The another package may include a substrate (e.g., laminated substrate), a second integrated device and another encapsulation layer. In some implementations, a plurality of integrated devices (e.g., stacked integrated devices) may be coupled to the package 100. In some implementations, a plurality of packages (e.g., stacked packages) may be coupled to the package 100.

### Exemplary Flow Diagram of a Method for Fabricating a Package

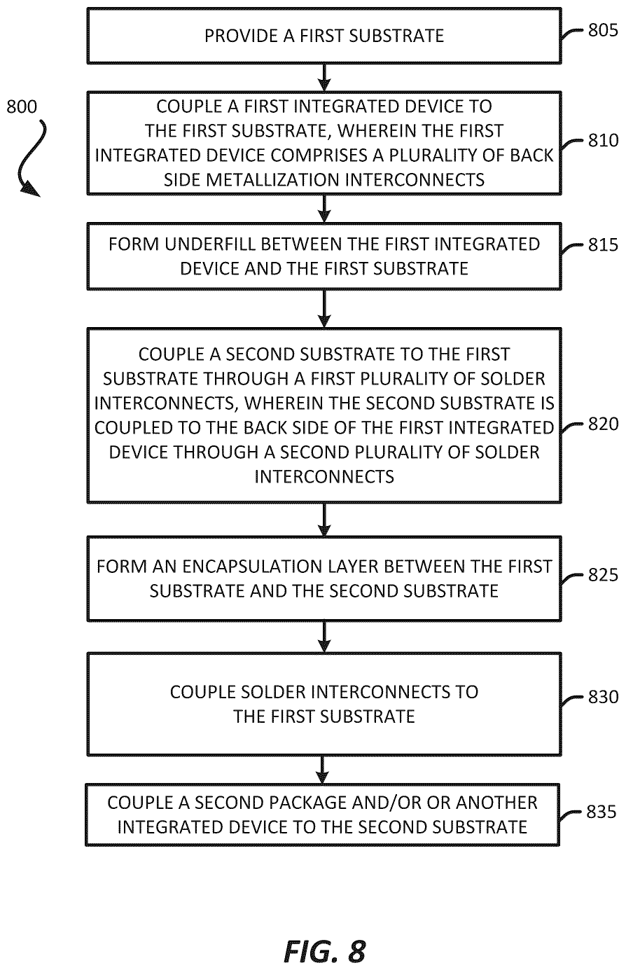

In some implementations, fabricating a package includes several processes. FIG. 8 illustrates an exemplary flow diagram of a method 800 for providing or fabricating a package. In some implementations, the method 800 of FIG. 8 may be used to provide or fabricate the package 800 or the package 800 described in the disclosure. However, the method 800 may be used to provide or fabricate any of the packages described in the disclosure.

It should be noted that the method 800 of FIG. 8 may combine one or more processes in order to simplify and/or clarify the method for providing or fabricating a package. In some implementations, the order of the processes may be changed or modified.

The method provides (at 805) a first substrate. Stage 1 of FIG. 6A, illustrates and describes an example of a state after a substrate 102 is provided. The substrate 102 may be a first substrate. The substrate 102 includes at least one dielectric layer 120, a plurality of interconnects 121, a solder resist layer 126 and a solder resist layer 128. The substrate 102 may include a first surface (e.g., top surface) and a second surface (e.g., bottom surface). The substrate 102 may be fabricated using a method similar to the method described below in FIGS. 9A-9B.

The method couples (at 810) a first integrated device to the first substrate. Stage 2 of FIG. 6A, illustrates and describes an example of a state after an integrated device 105 is coupled to the first surface (e.g., top surface) of the substrate 102. The integrated device 105 may be coupled to the substrate 102 through the plurality of pillar interconnects 150 and the plurality of solder interconnects 152. In some implementations, the integrated device 105 may be coupled to the substrate 102 through the plurality of solder interconnects 152. A solder reflow process may be used to couple the integrated device 105 to the substrate 102. The integrated device 105 may include a plurality of back side metallization interconnects 151. In some implementations, the integrated device 105 may include a plurality of post interconnects 153.

The method provides (at 815) an underfill between the integrated device and the first substrate. Stage 3 of FIG. 6A, illustrates and describes an example of a state after an underfill 156 is formed, dispensed and/or provided. The underfill 156 may be located vertically between the integrated device 105 and the substrate 102. A flow process may be used to provide the underfill 156.

The method couples (at 820) a second substrate to the first substrate through a first plurality of solder interconnects. The second substrate is coupled to a back side of the first integrated device through a second plurality of solder interconnects. Stage 4 of FIG. 6B, illustrates and describes an example of a state after the substrate 104 is coupled to the substrate 102 through the plurality of solder interconnects 107. The substrate 104 may also be coupled to the back side of the integrated device 105 through the plurality of solder interconnects 109. The plurality of solder interconnects 109 may be coupled to the plurality of back side metallization interconnects 151. A solder reflow process may be used to couple the substrate 104 to the substrate 102. The substrate 104 may be a second substrate. The substrate 104 may be an interposer. The substrate 104 includes at least one dielectric layer 140 (e.g., interposer dielectric layer) and a plurality of interconnects 141 (e.g., interposer interconnects). In some implementations, the substrate 104 may include a plurality of post interconnects 143.

The method forms (at 825) an encapsulation layer between the first substrate and the second substrate. Stage 5 of FIG. 6B, illustrates and describes an example of a state after an encapsulation layer 106 is provided between the substrate 102 and the substrate 104. The encapsulation layer 106 may include a mold, a resin, an epoxy and/or a filler. The encapsulation layer 106 may include a different material and/or a different composition from the underfill 156. The encapsulation layer 106 may be provided by using a compression and transfer molding process, a sheet molding process, or a liquid molding process.

The method couples (at 830) a plurality of solder interconnects to the first substrate. Stage 6 of FIG. 6B, illustrates and describes an example of a state after a plurality of solder interconnects 114 are coupled to the second surface of the substrate 102. A solder reflow process may be used to couple the plurality of solder interconnects 114 to the substrate 102. The plurality of solder interconnects 114 may be coupled to the plurality of interconnects 121.

The method couples (at 835) a second package to the second substrate. In some implementations, the method may couple a second integrated device (e.g., 205) to the second substrate through a plurality of solder interconnects (e.g., 250). A solder reflow process may be used to couple the second integrated device to the second substrate. In some implementations, a plurality of integrated devices (e.g., stacked integrated devices) may be coupled to the package 100. In some implementations, a plurality of packages (e.g., stacked packages) may be coupled to the package 100.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Substrate

In some implementations, fabricating a substrate includes several processes. FIGS. 9A-9B illustrate an exemplary sequence for providing or fabricating a substrate. In some implementations, the sequence of FIGS. 9A-9B may be used to provide or fabricate the substrate 104. However, the process of FIGS. 9A-9B may be used to fabricate any of the substrates described in the disclosure.

It should be noted that the sequence of FIGS. 9A-9B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 9A, illustrates a state after a carrier 900 is provided. A seed layer 901 may be located over the carrier 900.

Stage 2 illustrates a state after a plurality of interconnects 912 are formed. The interconnects 912 may be located over the seed layer 901. A lithography process, a plating process, a strip process and/or an etching process may be used to form the plurality of interconnects 912. The interconnects 912 may represent at least some of the interconnects from the plurality of interconnects 141.

Stage 3 illustrates a state after a dielectric layer 910 is formed over the carrier 900, the seed layer 901 and the plurality of interconnects 912. A deposition and/or lamination process may be used to form the dielectric layer 910. The dielectric layer 910 may include prepreg and/or polyimide. The dielectric layer 910 may include a photo-imageable dielectric. However, different implementations may use different materials for the dielectric layer.

Stage 4 illustrates a state after a plurality of cavities 913 is formed in the dielectric layer 910. The plurality of cavities 913 may be formed using an etching process (e.g., photo etching process), a laser process, an exposure process and/or a development process.

Stage 5 illustrates a state after interconnects 922 are formed in and over the dielectric layer 910, including in and over the plurality of cavities 913. For example, a via, pad and/or traces may be formed. A lithography process, a plating process, a strip process and/or an etching process may be used to form the interconnects.

Stage 6 illustrates a state after a photo resist layer 915 is formed over a portion of the dielectric layer 910 and/or over some portions of the interconnects 922. A deposition process may be used to form the photo resist layer 915.

Stage 7, as shown in FIG. 9B, illustrates a state after a dielectric layer 920 is formed over the dielectric layer 910 and the plurality of interconnects 922. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

Stage 8, illustrates a state after a plurality of cavities 923 are formed in the dielectric layer 140. The dielectric layer 140 may represent the dielectric layer 910 and/or the dielectric layer 920. The plurality of cavities 923 may be formed using an etching process (e.g., photo etching process), a laser process, an exposure process and/or a development process.

Stage 9 illustrates a state after interconnects 932 are formed in and over the dielectric layer 140, including in and over the plurality of cavities 923. For example, a via, pad and/or traces may be formed. A lithography process, a plating process, a strip process and/or an etching process may be used to form the interconnects.

Stage 10 illustrates a state after the photo resist layer 915 is removed, the carrier 900 is decoupled (e.g., detached, removed, grinded out) from at least one dielectric layer 140 and the seed layer 901, portions of the seed layer 901 are removed (e.g., etched out), leaving the substrate 104 that includes at least one dielectric layer 140 and the plurality of interconnects 141 and the cavity 108. The plurality of interconnects 141 may represent the plurality of interconnects 912, the plurality of interconnects 922 and/or the plurality of interconnects 932. Stage 10 may illustrates a substrate 104 that includes a cavity 108.

Stage 11 illustrates a state after the solder resist layer 146 is formed over a surface of the substrate 104. A deposition process and/or lamination process may be used to form the solder resist layer 146. The solder resist layer 146 may include openings. An etching process, an exposure process and/or a development process may be used to form the openings in the solder resist layer 146.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

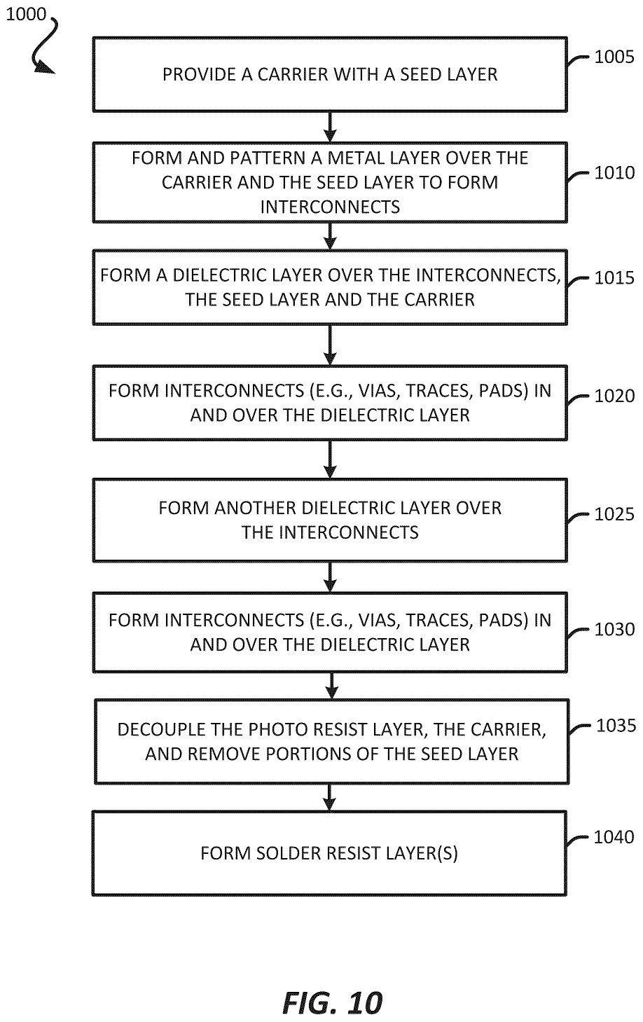

In some implementations, fabricating a substrate includes several processes. FIG. 10 illustrates an exemplary flow diagram of a method 1000 for providing or fabricating a substrate. In some implementations, the method 1000 of FIG. 10 may be used to provide or fabricate the substrate(s) of the disclosure. For example, the method 1000 of FIG. 10 may be used to fabricate the substrate 104.

It should be noted that the method 1000 of FIG. 10 may combine one or more processes in order to simplify and/or clarify the method for providing or fabricating a substrate. In some implementations, the order of the processes may be changed or modified.

The method provides (at 1005) a carrier with a seed layer. Stage 1 of FIG. 9A, illustrates and describes an example of a state after a carrier 900 is provided. A seed layer 901 may be located over the carrier 900.

The method forms and patterns (at 1010) a plurality of interconnects. Stage 2 of FIG. 9A, illustrates and describes an example of a state after a plurality of interconnects 912 are formed. The interconnects 912 may be located over the seed layer 901. A lithography process, a plating process, a strip process and/or an etching process may be used to form the plurality of interconnects 912. The interconnects 912 may represent at least some of the interconnects from the plurality of interconnects 141.

The method forms (at 1015) a dielectric layer. Stage 3 of FIG. 9A, illustrates and describes an example of a state after a dielectric layer 910 is formed over the carrier 900, the seed layer 901 and the plurality of interconnects 912. A deposition and/or lamination process may be used to form the dielectric layer 910. The dielectric layer 910 may include prepreg and/or polyimide. The dielectric layer 910 may include a photo-imageable dielectric. However, different implementations may use different materials for the dielectric layer.

The method forms (at 1020) a plurality of interconnects. Forming a plurality of interconnects may include forming a plurality of cavities in a dielectric layer and a performing a plating process. Stage 4 of FIG. 9A, illustrates and describes an example of a state after a plurality of cavities 913 is formed in the dielectric layer 910. The plurality of cavities 913 may be formed using an etching process (e.g., photo etching process), a laser process, an exposure process and/or a development process.

Stage 5 of FIG. 9A, illustrates and describes an example of a state after interconnects 922 are formed in and over the dielectric layer 910, including in and over the plurality of cavities 913. For example, a via, pad and/or traces may be formed. A lithography process, a plating process, a strip process and/or an etching process may be used to form the interconnects.

The method forms (at 1025) another dielectric layer. Stage 7 of FIG. 9B, illustrates and describes an example of a state after a dielectric layer 920 is formed over the dielectric layer 910 and the plurality of interconnects 922. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer. In some implementations, a photo resist layer (e.g., 915) may be formed over and coupled to a portion of the dielectric 910 before the dielectric layer 920 is formed. Stage 6 of FIG. 9A, illustrates and describes an example of a photo resist layer that is formed.

The method forms (at 1030) a plurality of interconnects. Forming a plurality of interconnects may include forming a plurality of cavities in a dielectric layer and a performing a plating process. Stage 8 of FIG. 9B, illustrates and describes an example of a state after a plurality of cavities 923 is formed in the dielectric layer 140. The dielectric layer 140 may represent the dielectric layer 910 and/or the dielectric layer 920. The plurality of cavities 923 may be formed using an etching process (e.g., photo etching process), a laser process, an exposure process and/or a development process.

Stage 9 of FIG. 9B, illustrates and describes an example of a state after interconnects 932 are formed in and over the dielectric layer 140, including in and over the plurality of cavities 923. For example, a via, pad and/or traces may be formed. A lithography process, a plating process, a strip process and/or an etching process may be used to form the interconnects.

The method decouples (at 1035) a carrier and removes the photo resist layer. Stage 10 of FIG. 9B, illustrates and describes an example of a state after the carrier 900 is decoupled (e.g., detached, removed, grinded out) from at least one dielectric layer 140 and the seed layer 901, portions of the seed layer 901 are removed (e.g., etched out), leaving the substrate 104 that includes at least one dielectric layer 140 and the plurality of interconnects 141 and a cavity 108. The photo resist layer 915 may also be removed. The plurality of interconnects 141 may represent the plurality of interconnects 912, the plurality of interconnects 922 and/or the plurality of interconnects 932.

The method forms (at 1040) solder resist layers. Stage 10 of FIG. 9B, illustrates and describes an example of a state after the solder resist layer 146 is formed over a surface of the substrate 104. A deposition process and/or lamination process may be used to form the solder resist layer 146. An etching process, an exposure process and/or a development process may be used to form the openings in the solder resist layer 146.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Package

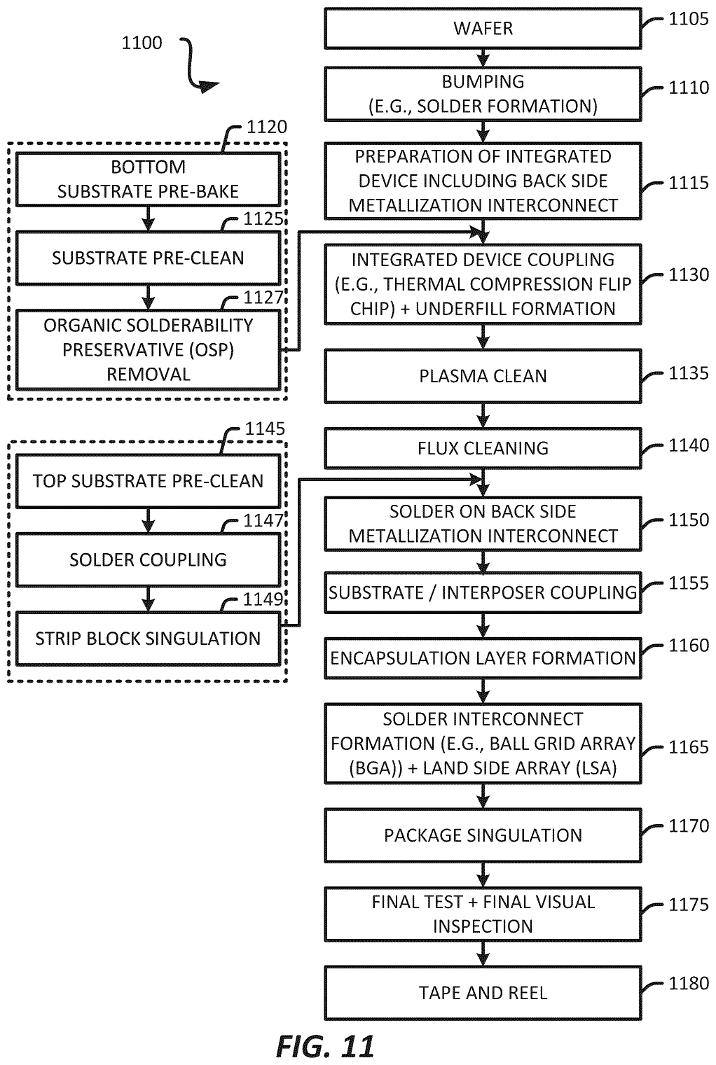

FIG. 11 illustrates an exemplary flow diagram of a method 1100 for providing or fabricating a package. In some implementations, the method 1100 of FIG. 11 may be used to provide or fabricate some or all of the packages (such as the package 100 of FIG. 1) described in the disclosure. However, the method 1100 may be used to provide or fabricate any of the packages described in the disclosure.

It should be noted that the method 1100 of FIG. 11 may combine one or more processes in order to simplify and/or clarify the method for providing or fabricating a package. In some implementations, the order of the processes may be changed or modified.

The method provides (at 1105) a wafer. The wafer may serve as a substrate on which integrated devices may be formed and/or coupled to. In some implementations, other substrates may be coupled to the wafer. The wafer may include silicon. The wafer may serve as a base on which components are built over.

The method forms (at 1110) solder interconnects on the wafer. A solder reflow process may be used to form (e.g., couple) solder interconnects on the wafer.

The method prepares (at 1115) one or more integrated devices (e.g., dies) for coupling. Preparing the integrated devices may include fabricating the integrated devices. In some implementations, preparing the integrated device may include forming a plurality of back side metallization interconnects (e.g., 151). In some implementations, preparing the integrated device may include forming a plurality of back side metallization interconnects (e.g., 151) and a plurality of post interconnects (e.g., 153) on the back side of the integrated device.

The method provides and prepares (at 1120) a first substrate (e.g., substrate 102, bottom substrate) by pre-baking the first substrate. The first substrate may be pre-baked to remove moisture on the first substrate to avoid outgassing during a subsequent thermal compression flip chip coupling process. The method pre-cleans (at 1125) the first substrate. The method removes (at 1127) organic solderability preservative (OSP) on the first substrate. Stage 1 of FIG. 6A, illustrates and describes an example of a first substrate that is provided.

Once the first substrate is provided and prepared, the first substrate may be coupled to the wafer through the solder interconnects that are formed on the wafer.

The integrated device(s) is/are coupled (at 1130) to the first substrate. For example, the integrated device 105 may be coupled to the substrate 102 through a thermal compression flip chip process. An underfill may be provided between the integrated device and the substrate. Stages 2 and 3 of FIG. 6A illustrate and describe an example of an integrated device that is coupled to a substrate and an underfill that is provided between the integrated device and the substrate.

The method performs (at 1135) a plasma clean of the first substrate. The plasma clean may remove contamination on the surface of the substrate.

The method performs (at 1140) a flux cleaning of one or more substrates. Flux cleaning may remove oxides from metal of the substrate. The flux cleaning may be performed on the first substrate and/or the second substrate.

The method pre-cleans (at 1145) a second substrate (e.g., substrate 104, top substrate). The method couples (at 1147) solder interconnects to the second substrate. In some implementations, the method may couple (at 1147) ball interconnects (e.g., copper core ball) to the second substrate. The ball interconnects may be coupled to the substrate 104 through solder interconnects (e.g., 107). A solder reflow process may be used to couple the solder interconnects to the second substrate. The method performs (at 1149) strip block singulation of the second substrate. This may be done, when several substrates are fabricated at the same time and then subsequently singulated.

The method forms (at 1150) solder interconnects (e.g., 109) on the back side of the integrated device (e.g., 105). For example, a plurality of solder interconnects 109 may be pasted on the plurality of back side metallization interconnects 151 of the integrated device 105 and/or the plurality of post interconnects 153 of the integrated device 105.

The method couples (at 1155) the second substrate (e.g., 104) to the first substrate (e.g., 102) through the solder interconnects. A solder reflow process may be used to couple the second substrate to the first substrate. Stage 4 of FIG. 6B, illustrates and describes an example of a second substrate that is provided and coupled to the first substrate through solder interconnects. The second substrate (e.g., 104) may also be coupled to the back side of the integrated device (e.g., 105) through the plurality of solder interconnects (e.g., 109).

The method provides (at 1160) an encapsulation layer (e.g., 106) between the first substrate and the second substrate. The encapsulation layer may also be provided between the first substrate and the heat sink. Stage 5 of FIG. 6D, illustrates and describes an example of providing an encapsulation layer between a first substrate and a second substrate.

The method forms (at 1165) solder interconnects or land side array (LSA) on the first substrate. A solder reflow process may be used to form the solder interconnects. The solder interconnects may be a ball grid array (BGA). Stage 6 of FIG. 6B, illustrates and describes an example of coupling a plurality of solder interconnects to a first substrate.

The method singulates (at 1170) the packages into individual packages. This may occur when several packages are fabricated at the same time. Singulating the package may include singulating the wafer that includes the first substrate(s), the integrated device(s), and the second substrate(s). A mechanical process (e.g., saw) or a laser may be used to singulate the packages.

The method performs (at 1175) a final test and final visual inspection of the package. This may include testing whether the package works properly by attaching probes to the package to determine whether the package works as intended. Visual inspection may include visually inspecting to see whether the package has any defects.

The method performs (at 1180) tape and reel of the packages. This may include packaging the singulated packages together with tape so that the package can be properly shipped.

It is noted that additional processes may be performed on the packages, including coupling other components, such as passive components and/or integrated devices to the packages. FIG. 11 illustrates an example of how packages may be fabricated. FIG. 11 is not intended to illustrate the only way that a package may be fabricated.

### Exemplary Electronic Devices

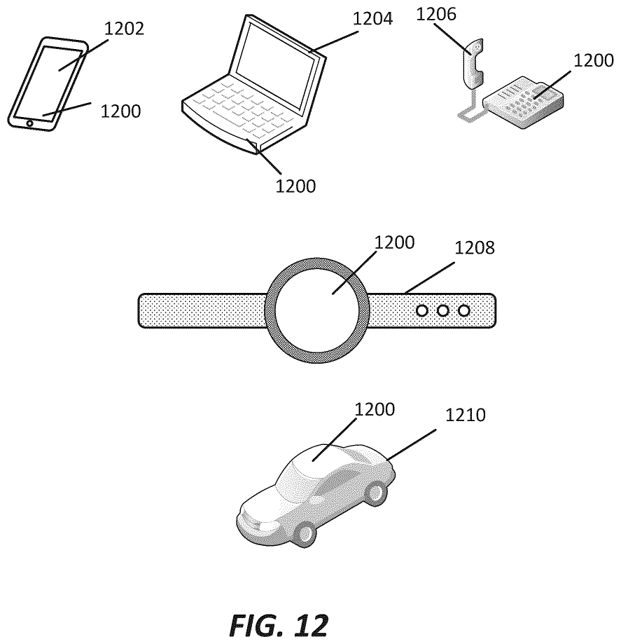

FIG. 12 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1202, a laptop computer device 1204, a fixed location terminal device 1206, a wearable device 1208, or automotive vehicle 1210 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6B, 7, 8, 9A-9B, and 10-12 may be rearranged and/or combined into a single component, process, feature or function or embodied in several components, processes, or functions. Additional elements, components, processes, and/or functions may also be added without departing from the disclosure. It should also be noted FIGS. 1-5, 6A-6B, 7, 8, 9A-9B, and 10-12 and its corresponding description in the present disclosure is not limited to dies and/or ICs. In some implementations, FIGS. 1-5, 6A-6B, 7, 8, 9A-9B, and 10-12 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a first substrate; an integrated device coupled to the first substrate, wherein the integrated device comprises a plurality of back side metallization interconnects; and a second substrate coupled to the first substrate through a first plurality of solder interconnects, wherein the second substrate is coupled to the plurality of back side metallization interconnects through a second plurality of solder interconnects.

Aspect 2: The package of aspect 1, further comprising an encapsulation layer located between the first substrate and the second substrate.

Aspect 3: The package of aspects 1 through 2, wherein the second plurality of solder interconnects touch the plurality of back side metallization interconnects.

Aspect 4: The package of aspects 1 through 3, wherein the second substrate comprises at least one dielectric layer; and a plurality of interconnects.

Aspect 5: The package of aspect 4, wherein the second plurality of solder interconnects is coupled to the plurality of interconnects.

Aspect 6: The package of aspects 4 through 5, wherein the plurality of interconnects includes a plurality of post interconnects.

Aspect 7: The package of aspect 6, wherein the second plurality of solder interconnects is coupled to the plurality of post interconnects.

Aspect 8: The package of aspects 4 through 5, wherein the integrated device further comprises a plurality of post interconnects coupled to the plurality of back side metallization interconnects.

Aspect 9: The package of aspect 8, wherein the second plurality of solder interconnects is coupled to and touch the plurality of post interconnects.

Aspect 10: The package of aspects 1 and 3-9, further comprising an encapsulation layer located between the first substrate and the second substrate; and an underfill located between the integrated device and the first substrate.

Aspect 11: The package of aspect 10, wherein the underfill includes a different material or a different composition from the encapsulation layer located between the first substrate and the second substrate.

Aspect 12: The package of aspects 1 through 11, further comprising a second integrated device coupled to the second substrate through a third plurality of solder interconnects.

Aspect 13: The package of aspects 1 through 12, further comprising another package coupled to the second substrate through a third plurality of solder interconnects.

Aspect 14: The package of aspects 1 through 13, wherein the integrated device is coupled to the first substrate through a plurality of pillar interconnects and/or a third plurality of solder interconnects.

Aspect 15: The package of aspects 1 through 14, wherein the second substrate includes a cavity, and wherein the cavity of the second substrate is at least partially filled with an encapsulation layer.

Aspect 16: The package of aspect 15, wherein the second plurality of solder interconnects is located at least partially in the cavity of the second substrate.

Aspect 17: The package of aspects 1 through 16, wherein the integrated device comprises a die substrate, and wherein the die substrate is free of any through substrate vias.

Aspect 18: The package of aspect 17, wherein the plurality of back side metallization interconnects is coupled to a surface of the die substrate.

Aspect 19: The package of aspects 17 through 18, wherein an electrical path through the plurality of back side metallization interconnects does not extend through the die substrate.

Aspect 20: The package of aspects 17 through 19, wherein an electrical path to and/or from the integrated device only extend through a front side of the integrated device.

Aspect 21: A method for fabricating a package. The method provides a first substrate. The method couples an integrated device to the first substrate, wherein the integrated device comprises a plurality of back side metallization interconnects. The method couples a second substrate to the first substrate through a first plurality of solder interconnects, wherein the second substrate is coupled to the plurality of back side metallization interconnects through a second plurality of solder interconnects.

Aspect 22: The method of aspect 21, further comprising forming an encapsulation layer between the first substrate and the second substrate.

Aspect 23: The method of aspects 21 through 22, wherein the second plurality of solder interconnects touch the plurality of back side metallization interconnects.

Aspect 24: The method of aspects 21 through 23, wherein the second substrate comprises at least one dielectric layer; and a plurality of interconnects.

Aspect 25: The method of aspect 24, wherein the second plurality of solder interconnects is coupled to the plurality of interconnects.

Aspect 26: The method of aspects 24 through 25, wherein the plurality of interconnects includes a plurality of post interconnects.

Aspect 27: The method of aspect 26, wherein the second plurality of solder interconnects is coupled to the plurality of post interconnects.

Aspect 28: The method of aspects 24 through 25, wherein the integrated device further comprises a plurality of post interconnects coupled to the plurality of back side metallization interconnects.

Aspect 29: The method of aspect 28, wherein the second plurality of solder interconnects is coupled to and touch the plurality of post interconnects.

Aspect 30: The method of aspects 21 and 23-29, further comprising forming an encapsulation layer between the first substrate and the second substrate; and forming an underfill located the integrated device and the first substrate.

Aspect 31: The method of aspect 30, wherein the underfill includes a different material or a different composition from the encapsulation layer located between the first substrate and the second substrate.

Aspect 32: The method of aspects 21 through 31, further comprising coupling a second integrated device to the second substrate through a third plurality of solder interconnects.

Aspect 33: The method of aspects 21 through 32, further comprising coupling another package to the second substrate through a third plurality of solder interconnects.

Aspect 34: The method of aspects 21 through 33, wherein the integrated device is coupled to the first substrate through a plurality of pillar interconnects and/or a third plurality of solder interconnects.

Aspect 35: The method of aspects 21 through 34, wherein the second substrate includes a cavity, and wherein the cavity of the second substrate is at least partially filled with an encapsulation layer.

Aspect 36: The method of aspect 35, wherein the second plurality of solder interconnects is located at least partially in the cavity of the second substrate.

Aspect 37: The method of aspects 21 through 36, wherein the integrated device comprises a die substrate, and wherein the die substrate is free of any through substrate vias.

Aspect 38: The method of aspect 37, wherein the plurality of back side metallization interconnects is coupled to a surface of the die substrate.

Aspect 39: The method of aspects 37 through 38, wherein an electrical path through the plurality of back side metallization interconnects does not extend through the die substrate.

Aspect 40: The method of aspects 37 through 39, wherein an electrical path to and/or from the integrated device only extend through a front side of the integrated device.

Aspect 41: The method of aspects 21 through 40, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 42: The package of aspects 1 through 20, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first substrate;
an integrated device coupled to the first substrate, wherein the integrated device comprises a plurality of back side metallization interconnects; and
a second substrate coupled to the first substrate through a first plurality of solder interconnects, wherein the second substrate is coupled to the plurality of back side metallization interconnects through a second plurality of solder interconnects.

2. The package of claim 1, further comprising an encapsulation layer located between the first substrate and the second substrate.

3. The package of claim 1, wherein the second plurality of solder interconnects touch the plurality of back side metallization interconnects.

4. The package of claim 1, wherein the second substrate comprises:
at least one dielectric layer; and
a plurality of interconnects.

5. The package of claim 4, wherein the second plurality of solder interconnects is coupled to the plurality of interconnects.

6. The package of claim 4, wherein the plurality of interconnects includes a plurality of post interconnects.

7. The package of claim 6, wherein the second plurality of solder interconnects is coupled to the plurality of post interconnects.

8. The package of claim 4, wherein the integrated device further comprises a plurality of post interconnects coupled to the plurality of back side metallization interconnects.

9. The package of claim 8, wherein the second plurality of solder interconnects is coupled to and touch the plurality of post interconnects.

10. The package of claim 1, further comprising:
an encapsulation layer located between the first substrate and the second substrate; and
an underfill located between the integrated device and the first substrate.

11. The package of claim 10, wherein the underfill includes a different material or a different composition from the encapsulation layer located between the first substrate and the second substrate.

12. The package of claim 1, further comprising a second integrated device coupled to the second substrate through a third plurality of solder interconnects.

13. The package of claim 1, further comprising another package coupled to the second substrate through a third plurality of solder interconnects.

14. The package of claim 1, wherein the integrated device is coupled to the first substrate through a plurality of pillar interconnects and/or a third plurality of solder interconnects.

15. The package of claim 1,
wherein the second substrate includes a cavity, and
wherein the cavity of the second substrate is at least partially filled with an encapsulation layer.

16. The package of claim 15, wherein the second plurality of solder interconnects is located at least partially in the cavity of the second substrate.

17. The package of claim 1,
wherein the integrated device comprises a die substrate, and
wherein the die substrate is free of any through substrate vias.

18. The package of claim 17, wherein the plurality of back side metallization interconnects is coupled to a surface of the die substrate.

19. The package of claim 17, wherein an electrical path through the plurality of back side metallization interconnects does not extend through the die substrate.

20. The package of claim 17, wherein an electrical path to and/or from the integrated device only extend through a front side of the integrated device.
